(19) United States
(12) Patent Application Publication
(10) Pub. No.: US 2025/0046887 A1
(43) Pub. Date: Feb. 6, 2025

(54) BATTERY MANAGEMENT SYSTEM

(71) Applicant: Nuvoton Technology Corporation Japan, Kyoto (JP)

(72) Inventors: Susumu YOSHIKAWA, Shiga (JP); Hitoshi KOBAYASHI, Osaka (JP); Keiichi FUJII, Shiga (JP); Akira KAWABE, Osaka (JP)

(21) Appl. No.: 18/924,580

(22) Filed: Oct. 23, 2024

Related U.S. Application Data
(63) Continuation of application No. PCT/JP2023/016345, filed on Apr. 25, 2023.
(60) Provisional application No. 63/335,435, filed on Apr. 27, 2022.

(51) Int. Cl. H01M 10/42; B60L 58/10; H01M 10/48; H01M 50/209; H01M 50/249; H01M 50/271; H01Q 1/22

(52) U.S. Cl. CPC H01M 10/425; H01M 10/482; H01M 50/209; H01M 50/249; H01M 50/271; H01Q 1/22; B60L 58/10; H01M 2010/4271; H01M 2220/20

(57) ABSTRACT

A BMS for managing a battery assembly includes: a BMU that manages the battery assembly and includes a communication antenna; and one or more CMUs that monitor the battery assembly and each include a communication antenna that communicates with the communication antenna. A communication antenna group including the communication antenna and one or more communication antennas is arranged in a straight line. The BMS further includes a conductor that covers at least part of the communication antenna group. The conductor includes a recess that extends in the alignment direction of the communication antenna group and is recessed in a direction away from the communication antenna group in a cross-section orthogonal to the alignment direction.

### CROSS REFERENCE TO RELATED APPLICATIONS

This is a continuation application of PCT International Application No. PCT/JP2023/016345 filed on Apr. 25, 2023, designating the United States of America, which is based on and claims priority of U.S. Provisional Patent Application No. 63/335,435 filed on Apr. 27, 2022. The entire disclosures of the above-identified applications, including the specifications, drawings, and claims are incorporated herein by reference in their entirety.

### FIELD

The present disclosure relates to a battery management system for managing a battery assembly.

### BACKGROUND

There is a battery management system including a battery assembly that includes a plurality of battery cells (for example, see Patent Literature (PTL) 1). The battery management system manages the battery assembly by having elements included in the battery management system transmit and receive information via wireless communication.

### CITATION LIST

### Patent Literature

PTL 1: U.S. Patent Application Publication No. 2021/0305681

### SUMMARY

### Technical Problem

In a battery management system including a battery assembly, there is a problem that normal wireless communication may be hindered due to a relatively narrow space in which electromagnetic waves (also referred to as radio waves) propagate, or due to interference from radio waves arriving from outside (also referred to as incoming waves).

The present disclosure provides a battery management system and the like that can inhibit degradation of wireless communication quality.

### Solution to Problem

A battery management system according to the present disclosure is for managing a battery assembly, and includes: a management circuit that manages the battery assembly and includes a first communication antenna; and one or more monitoring circuits that monitor the battery assembly and each include a second communication antenna that communicates with the first communication antenna. A communication antenna group including the first communication antenna and one or more second communication antennas is aligned in a straight line, each of the one or more second communication antennas being the second communication antenna. The battery management system further includes a conductor that covers at least part of the communication antenna group. The conductor includes a recess that extends in an alignment direction of the communication antenna group and is recessed in a direction away from the communication antenna group in a cross-section orthogonal to the alignment direction.

General or specific aspects of the present disclosure may be realized as a system, a method, an integrated circuit, a computer program, a computer-readable recording medium such as CD-ROM, or any given combination thereof.

### Advantageous Effects

According to the present disclosure, degradation of wireless communication quality can be inhibited.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a first external view illustrating one example of a battery management system according to an embodiment of the present disclosure.

FIG. 2 is a second external view illustrating one example of a battery management system according to an embodiment of the present disclosure.

FIG. 3 is a configuration diagram illustrating one example of a battery management system according to an embodiment of the present disclosure.

FIG. 4 is a configuration diagram illustrating one example of a wireless communication circuit included in a cell monitoring circuit according to an embodiment of the present disclosure.

FIG. 5 is a configuration diagram illustrating one example of a voltage monitoring circuit included in a cell monitoring circuit according to an embodiment of the present disclosure.

FIG. 6 is a configuration diagram illustrating one example of a current measurement circuit included in a current monitoring circuit according to an embodiment of the present disclosure.

FIG. 7 is a configuration diagram illustrating one example of a wireless communication circuit included in a management circuit according to an embodiment of the present disclosure.

FIG. 8 is a configuration diagram illustrating one example of an MCU included in a management circuit according to an embodiment of the present disclosure.

FIG. 9 is a cross-sectional view illustrating one example of a cross-section of the battery management system taken along line IX-IX illustrated in FIG. 1.

FIG. 10 is an explanatory diagram of the recess in the cross-sectional view of FIG. 9.

FIG. 11 is a third external view illustrating one example of a battery management system according to an embodiment of the present disclosure.

### DESCRIPTION OF EMBODIMENT(S)

### Underlying Knowledge Forming the Basis of the Present Disclosure

There is a battery management system that manages a battery assembly including a plurality of battery cells. The battery assembly is used, for example, as a battery for an electric vehicle.

The battery management system includes a plurality of monitoring circuits that monitor the current or voltage of the battery cells, and a management circuit that manages the battery assembly using the plurality of monitoring circuits. The monitoring circuit includes a current monitoring circuit that monitors current flowing in a battery cell, or a cell monitoring circuit that monitors voltage of a battery cell.

In the battery management system, it is assumed that the management circuit and the monitoring circuit manage the battery assembly by transmitting and receiving information via wireless communication. By utilizing wireless communication, the battery management system has the advantage of not needing to include cables required for wired communication.

However, radio waves of wireless communication performed by the battery management system may interfere with incoming waves arriving from outside. When the battery management system is to be provided in a vehicle, due to the limited space in which radio waves propagate, the attenuation of radio waves may be relatively large. Due to these factors, there is a problem that the quality of the wireless communication performed by the battery management system may degrade, and normal wireless communication may be hindered.

The present disclosure provides a battery management system and the like that can inhibit degradation of wireless communication quality.

The present disclosure has an object to overcome such a problem and provide a battery management system and the like that contributes to reducing power consumption required for processing for managing a battery assembly.

Hereinafter, one or more embodiments of the present disclosure will be described in detail with reference to the drawings.

Each embodiment described below illustrates a general or specific example. The numerical values, shapes, materials, elements, the arrangement and connection of the elements, etc., shown in the following embodiments are mere examples, and therefore do not limit the scope of the present disclosure.

### EMBODIMENT

In the present embodiment, a battery management system that inhibits wireless communication quality from degrading will be described.

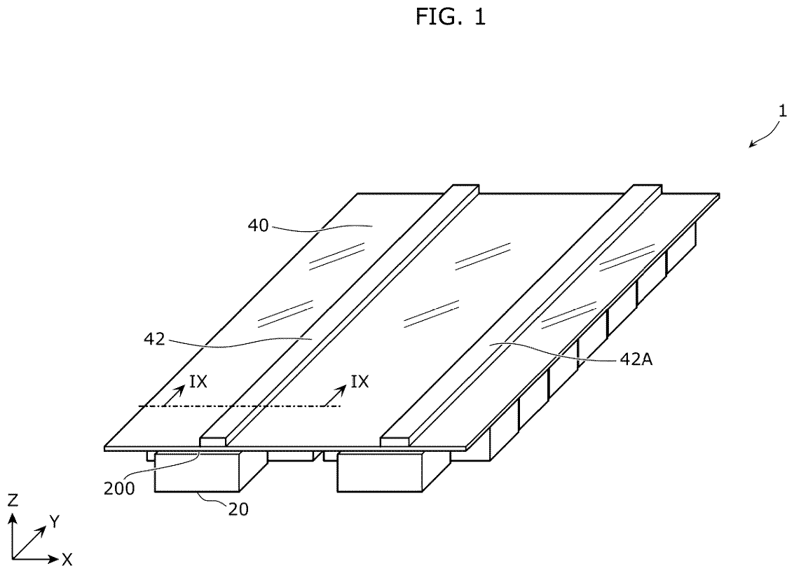

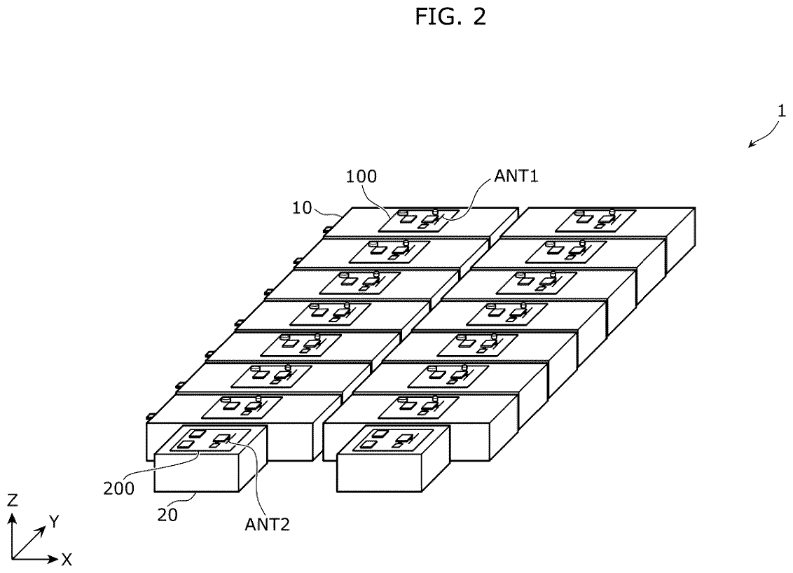

FIG. 1 and FIG. 2 are external views illustrating one example of battery management system (hereinafter also “BMS”) 1 according to the present embodiment.

BMS 1 is a system for managing a battery assembly. For example, BMS 1 manages the state of charge (SOC), state of health (SOH), and state of power (SOP) of the battery assembly. BMS 1 monitors anomalies in the battery assembly. BMS 1 includes management circuit 200 that manages the battery assembly, and a plurality of monitoring circuits 100 that monitor the battery assembly. For example, the battery assembly includes a plurality of battery packs 10 connected in series or parallel. Battery pack 10 includes one or more battery cells. When battery pack 10 includes a plurality of battery cells, the plurality of battery cells are connected in series.

For example, there are one or more monitoring circuits 100, and they are disposed on each of the plurality of battery packs 10. Specific examples of monitoring circuit 100, namely cell monitoring unit (CMU) 101 and current monitoring unit (CMU) 301, will be described later.

For example, management circuit 200 is connected to a battery assembly via junction box 20. Specific examples of management circuit 200, namely battery management unit (BMU) 201, will be described later.

BMS 1 includes cover 40 disposed on one or more battery cells. FIG. 1 illustrates BMS 1 with cover 40 in place, and FIG. 2 illustrates BMS 1 with cover 40 removed. During use, cover 40 is in place on BMS 1.

Cover 40 includes a conductor (for example, conductors 42 and 42A in FIG. 1) in a portion thereof. The characteristics of the conductor included in cover 40 will be explained in detail later.

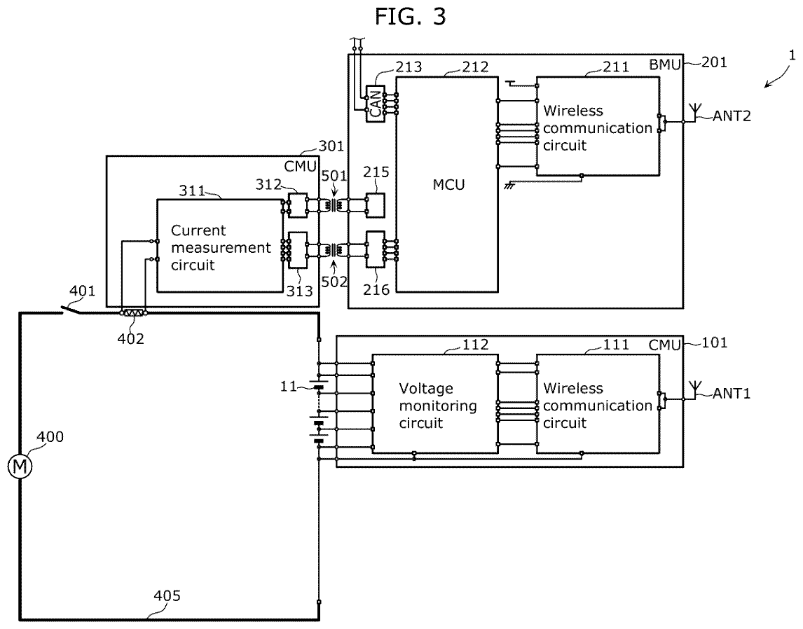

FIG. 3 is a configuration diagram illustrating one example of BMS 1 according to the present embodiment.

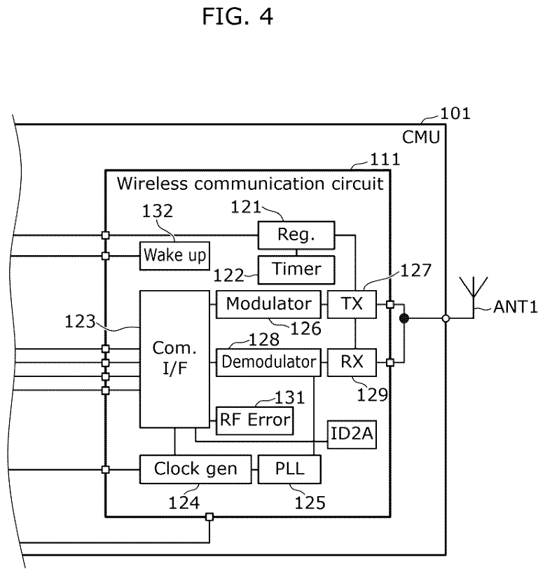

FIG. 4 is a configuration diagram illustrating one example of wireless communication circuit 111 included in the first cell monitoring circuit (CMU 101). Note that FIG. 4 also illustrates elements peripheral to wireless communication circuit 111 in the configuration diagram of FIG. 3.

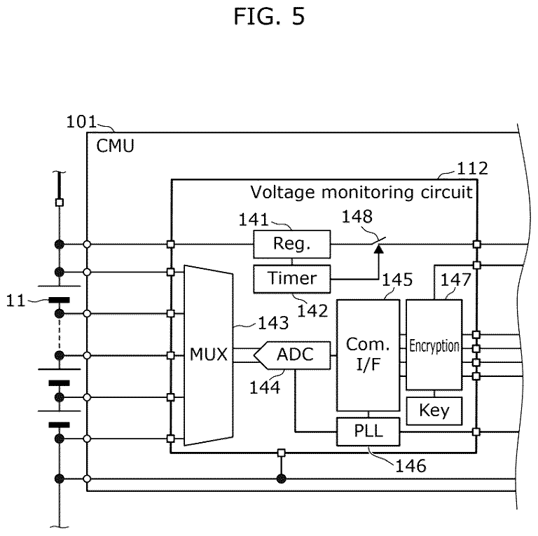

FIG. 5 is a configuration diagram illustrating one example of voltage monitoring circuit 112 included in the first cell monitoring circuit (CMU 101). Note that FIG. 5 also illustrates elements peripheral to voltage monitoring circuit 112 in the configuration diagram of FIG. 3.

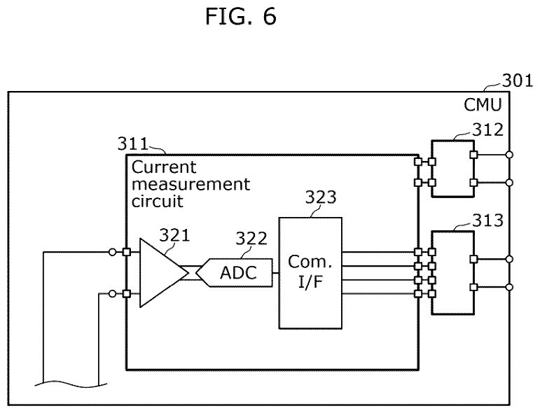

FIG. 6 is a configuration diagram illustrating one example of current measurement circuit 311 included in the current monitoring circuit (CMU 301). Note that FIG. 6 also illustrates elements peripheral to current measurement circuit 311 in the configuration diagram of FIG. 3.

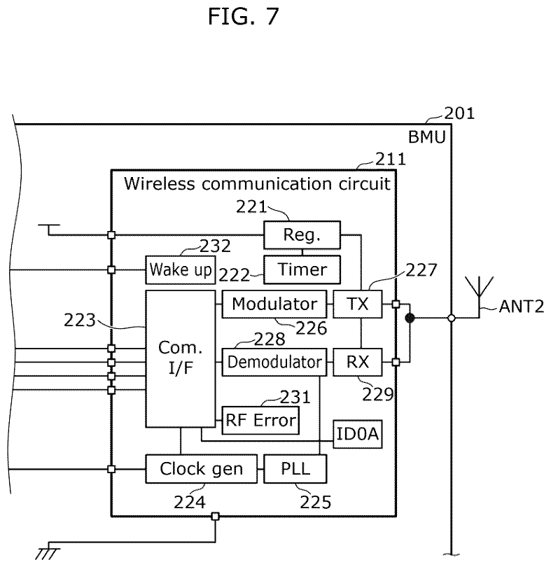

FIG. 7 is a configuration diagram illustrating one example of wireless communication circuit 211 included in the management circuit (BMU 201). Note that FIG. 7 also illustrates elements peripheral to wireless communication circuit 211 in the configuration diagram of FIG. 3.

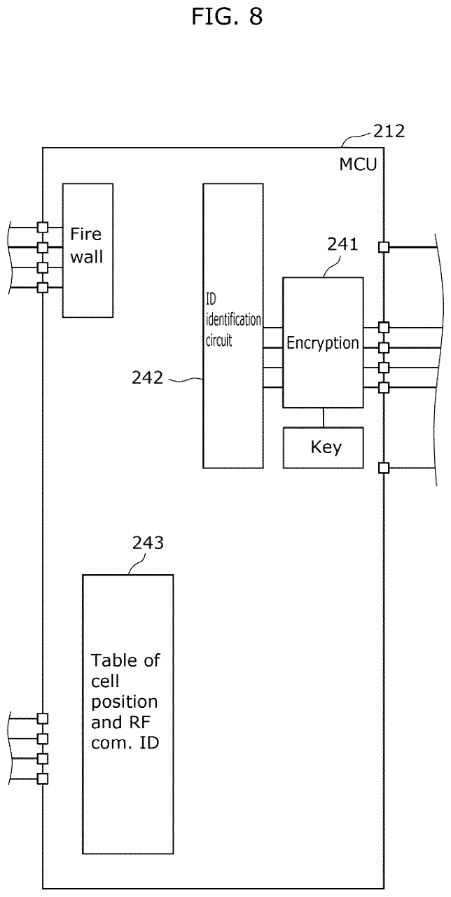

FIG. 8 is a configuration diagram illustrating one example of MCU 212 included in the management circuit (BMU 201). Note that FIG. 8 also illustrates elements peripheral to MCU 212 in the configuration diagram of FIG. 3.

FIG. 3 focuses on one battery pack 10 among the plurality of battery packs 10. FIG. 3 illustrates a plurality of battery cells 11 included in one battery pack 10 in the battery assembly as the one or more battery cells included in the battery assembly. CMU 101 is illustrated as monitoring circuit 100, and BMU 201 is illustrated as management circuit 200. Motor 400 is illustrated as a load to which power is supplied from the battery assembly. Moreover, power line 405 (bus bar) connecting the battery assembly and motor 400, and relay 401 and shunt resistor 402 inserted in power line 405 are also illustrated.

Relay 401 is a switch for interrupting current flowing in power line 405. For example, relay 401 is turned off to interrupt current flowing in power line 405 when the current monitored by CMU 301 is determined to be anomalous. Also, for example, relay 401 is turned off to interrupt current flowing in power line 405 when the voltage monitored by CMU 101 is determined to be anomalous.

Shunt resistor 402 is a resistor for measuring current flowing in power line 405.

CMU 101 is one example of a cell monitoring circuit that monitors one or more battery cells included in the battery assembly. For example, CMU 101 monitors the voltage of each of a plurality of battery cells 11.

As illustrated in FIG. 3, CMU 101 includes wireless communication circuit 111 and communication antenna ANT1 for communicating with BMU 201. Communication antenna ANT1 is capable of communicating with communication antenna ANT2 included in BMU 201. Communication antenna ANT1 corresponds to the second communication antenna. When a plurality of CMUs 101 are provided, communication antennas ANT1 of the plurality of CMUs 101 are arranged in a straight line.

Note that when a plurality of CMUs 101 are provided, it is not necessary for communication antennas ANT1 of all CMUs 101 to be arranged in a single straight line; it is sufficient if communication antennas ANT1 of some of the plurality of CMUs 101 are arranged in a straight line. In such cases, communication antennas ANT1 of CMUs 101 other than the communication antennas ANT1 of the CMUs 101 that are arranged in a straight line may be arranged in a different single straight line. FIG. 2 illustrates a configuration in which a plurality of communication antennas ANT1 arranged in two straight lines.

CMU 101 includes voltage monitoring circuit 112 that monitors the voltage of each of the plurality of battery cells 11. For example, wireless communication circuit 111 and voltage monitoring circuit 112 are each implemented by different integrated circuits (ICs). Note that wireless communication circuit 111 and voltage monitoring circuit 112 may be implemented by a single IC.

As illustrated in FIG. 4, wireless communication circuit 111 includes voltage conversion circuit (Reg.) 121, timer circuit (Timer) 122, communications interface (Com. I/F) 123, clock generation circuit (Clock gen) 124, phase-locked loop (PLL) 125, modulation circuit (Modulator) 126, transmission circuit (Tx) 127, demodulation circuit (Demodulator) 128, reception circuit (Rx) 129, communication error determination circuit (RF Error) 131, and wake-up circuit (Wake up) 132.

Voltage conversion circuit 121 is a circuit that converts the voltage input from voltage monitoring circuit 112 to a voltage for operating wireless communication circuit 111 and outputs the converted voltage.

Timer circuit 122 is a circuit that counts time. For example, timer circuit 122 is used to operate wireless communication circuit 111 intermittently.

Communications interface 123 is an interface for performing communication between wireless communication circuit 111 and voltage monitoring circuit 112. The identification information “ID2A” is associated with communications interface 123. Note that the identification information of communications interface 123 may be stored in any memory included in wireless communication circuit 111. Note that when wireless communication circuit 111 and voltage monitoring circuit 112 are implemented by a single IC, communications interface 123 may be omitted.

Clock generation circuit 124 is a circuit for generating a clock in CMU 101.

Phase-locked loop 125 is a circuit that adjusts the phase of a local signal to match the phase of a received signal.

Modulation circuit 126 is a circuit that modulates signals to be transmitted to BMU 201.

Transmission circuit 127 is a circuit for transmitting signals to BMU 201. Transmission circuit 127 transmits signals to BMU 201 via communication antenna ANT1.

Demodulation circuit 128 is a circuit that demodulates signals received from BMU 201.

Reception circuit 129 is a circuit for receiving signals from BMU 201. Reception circuit 129 receives signals from BMU 201 via communication antenna ANT1.

Communication error determination circuit 131 is a circuit that determines whether an anomaly has occurred in the communication between CMU 101 and BMU 201.

Wake-up circuit 132 is a circuit for activating voltage monitoring circuit 112. Wake-up circuit 132 is connected to encryption circuit 147, etc., of voltage monitoring circuit 112, and activates voltage monitoring circuit 112 by transmitting a wake-up signal.

As illustrated in FIG. 5, voltage monitoring circuit 112 includes voltage conversion circuit (Reg.) 141, timer circuit (Timer) 142, multiplexer (MUX) 143, AD converter (ADC) 144, communications interface (Com. I/F) 145, phase-locked loop (PLL) 146, encryption circuit (Encryption) 147, and switch 148.

Voltage conversion circuit 141 is a circuit that converts the voltage input from battery assembly to a voltage for operating voltage monitoring circuit 112 and wireless communication circuit 111 and outputs the converted voltage.

Timer circuit 142 is a circuit that counts time. Timer circuit 142 is connected to switch 148. Timer circuit 142 is a circuit for operating wireless communication circuit 111 intermittently. Timer circuit 142 turns on switch 148 by transmitting, upon elapse of a set amount of time (also referred to as timeout), a control signal that turns on switch 148. Timer circuit 142 turns off switch 148 by transmitting, upon elapse of a set amount of time after transmitting the control signal that turns on switch 148, a control signal that turns off switch 148.

Multiplexer 143 selects one battery cell 11 from among the plurality of battery cells 11 and outputs the terminal voltage of the selected battery cell 11. Stated differently, multiplexer 143 can output the voltage of each of the plurality of battery cells 11.

AD converter 144 converts the voltage value (analog value) of battery cell 11 selected by multiplexer 143 into a digital value.

Communications interface 145 is an interface for performing communication between wireless communication circuit 111 and voltage monitoring circuit 112. Note that when wireless communication circuit 111 and voltage monitoring circuit 112 are implemented by a single IC, communications interface 145 may be omitted.

Phase-locked loop 146 is a circuit that adjusts the phase of a local signal to match the phase of a received signal.

Encryption circuit 147 is a circuit that encrypts and decrypts signals. For example, encryption circuit 147 encrypts signals to be transmitted to wireless communication circuit 111 and ultimately to BMU 201, using an encryption key (Key).

Switch 148 is a switch that toggles on and off the power supply to wireless communication circuit 111, and is, for example, a transistor or the like. The on and off states of switch 148 may be controlled by a control signal from timer circuit 142.

CMU 101 detects the voltage value of each of the plurality of battery cells 11 using voltage monitoring circuit 112, and transmits the detected voltage values to BMU 201 using wireless communication circuit 111.

As illustrated in FIG. 3, CMU 301 includes current measurement circuit 311 that monitors current flowing in the battery assembly. CMU 301 includes power supply circuit 312 and insulated communication circuit 313.

Power supply circuit 312 is a circuit for supplying power to CMU 301, and supplies to CMU 301 power that has been supplied from BMU 201. For example, power supply circuit 312 is supplied with power from BMU 201 via transformer 501.

Insulated communication circuit 313 is a circuit for performing communication between CMU 301 and BMU 201 while maintaining insulation between CMU 301 and BMU 201. For example, insulated communication circuit 313 can perform communication between CMU 301 and BMU 201 while maintaining insulation between CMU 301 and BMU 201 by using transformer 502.

Current measurement circuit 311 is a circuit that measures current flowing in the battery assembly. More specifically, current measurement circuit 311 measures the current flowing in power line 405, that is, the current flowing in the battery assembly, by measuring the voltage generated when current flows through shunt resistor 402 provided on power line 405. As illustrated in FIG. 5, current measurement circuit 311 includes amplification circuit 321, AD converter (ADC) 322, and communications interface (Com. I/F) 323.

Amplification circuit 321 amplifies the voltage generated across shunt resistor 402. Amplification circuit 321 is provided because the resistance value of shunt resistor 402 is extremely small, and the voltage generated across shunt resistor 402 is also small.

AD converter 322 converts the voltage value (analog value) generated across shunt resistor 402 into a digital value.

Communications interface 323 is an interface for performing communication between CMU 301 and BMU 201.

As illustrated in FIG. 3, BMU 201 includes wireless communication circuit 211 and communication antenna ANT2 for communicating with CMU 101. Communication antenna ANT2 corresponds to the first communication antenna. Communication antenna ANT2 is arranged in a straight line together with communication antennas ANT1 of CMUs 101 that are arranged in a straight line. Communication antennas ANT1 and ANT2 are also collectively referred to as a communication antenna group.

BMU 201 also includes a micro controller unit (MCU) 212 for managing the battery assembly and a controller area network (CAN) interface 213. Note that wireless communication circuit 211 and MCU 212 may be implemented by a single IC (for example, a single MCU). BMU 201 includes power supply circuit 215 and insulated communication circuit 216.

CAN interface 213 is a communications interface that is connected to a CAN included in the vehicle equipped with the battery assembly.

Power supply circuit 215 is a circuit for supplying power to CMU 301. For example, power supply circuit 215 supplies power to CMU 301 via transformer 501.

Insulated communication circuit 216 is a circuit for performing communication between CMU 301 and BMU 201 while maintaining insulation between CMU 301 and BMU 201. For example, insulated communication circuit 216 can perform communication between CMU 301 and BMU 201 while maintaining insulation between CMU 301 and BMU 201 by using transformer 502.

CMU 301 monitors the current flowing in the high-voltage battery assembly of several hundred volts and handles high voltages, whereas BMU 201 handles voltages of only a few volts. Therefore, CMU 301 and BMU 201 are insulated by being connected via transformers 501 and 502.

As illustrated in FIG. 7, wireless communication circuit 211 includes voltage conversion circuit (Reg.) 221, timer circuit (Timer) 222, communications interface (Com. I/F) 223, clock generation circuit (Clock gen) 224, phase-locked loop (PLL) 225, modulation circuit (Modulator) 226, transmission circuit (Tx) 227, demodulation circuit (Demodulator) 228, reception circuit (Rx) 229, communication error determination circuit (RF Error) 231, and wake-up circuit (Wake up) 232. FIG. 7 illustrates “ID0A” as the identification information of wireless communication circuit 211. Note that the identification information of communications interface 223 may be stored in any memory included in wireless communication circuit 211.

Voltage conversion circuit 221 is a circuit that converts the voltage input from any power source to a voltage for operating wireless communication circuit 211 and outputs the converted voltage.

Timer circuit 222 is a circuit that counts time.

Communications interface 223 is an interface for performing communication between wireless communication circuit 211 and MCU 212. Note that when wireless communication circuit 211 and MCU 212 are implemented by a single IC, communications interface 223 may be omitted.

Clock generation circuit 224 is a circuit for generating a clock in BMU 201.

Phase-locked loop 225 is a circuit that adjusts the phase of a local signal to match the phase of a received signal.

Modulation circuit 226 is a circuit that modulates signals to be transmitted to CMU 101.

Transmission circuit 227 is a circuit for transmitting signals to CMU 101. Transmission circuit 227 transmits signals to CMU 101 via communication antenna ANT2.

Demodulation circuit 228 is a circuit that demodulates signals received from CMU 101.

Reception circuit 229 is a circuit for receiving signals from CMU 101. Reception circuit 229 receives signals from CMU 101 via communication antenna ANT2.

Communication error determination circuit 231 is a circuit that determines whether an anomaly has occurred in the communication between CMU 101 and BMU 201.

Wake-up circuit 232 is a circuit for activating MCU 212.

As illustrated in FIG. 8, MCU 212 includes encryption circuit (Encryption) 241 and identification circuit (ID identification circuit) 242. MCU 212 is connected to a CAN via CAN interface 213. A firewall is provided between MCU 212 and the CAN. MCU 212 also stores table (table of cell position and RF com. ID) 243 showing the correspondence between the positions of each of the plurality of battery cells 11 in battery pack 10 and identification information such as the wireless communication circuit of CMU 101 of each battery pack 10.

Encryption circuit 241 is a circuit that encrypts and decrypts signals. For example, encryption circuit 241 decrypts signals (for example, voltage values of battery cell 11) transmitted from CMU 101, using an encryption key (Key).

Identification circuit 242 uses table 243 to identify which position of battery cell 11 in which battery pack 10 the voltage value of battery cell 11 included in the signal transmitted from CMU 101 corresponds to.

Next, the conductor, which is a part of cover 40, will be described.

As illustrated in FIG. 1, cover 40 includes conductors 42 and 42A as examples of conductors. In FIG. 1, the communication antenna group is arranged in two rows at different positions in the X-axis direction. Among the two rows of the communication antenna group arranged in parallel, conductor 42 is positioned to cover the row of the communication antenna group located in the negative X-axis direction relative to the other row of the communication antenna group, and conductor 42A is positioned to cover the row of the communication antenna group located in the positive X-axis direction relative to the other row of the communication antenna group.

Hereinafter, conductor 42 will be described. The description of conductor 42A is omitted as it is similar to that of conductor 42.

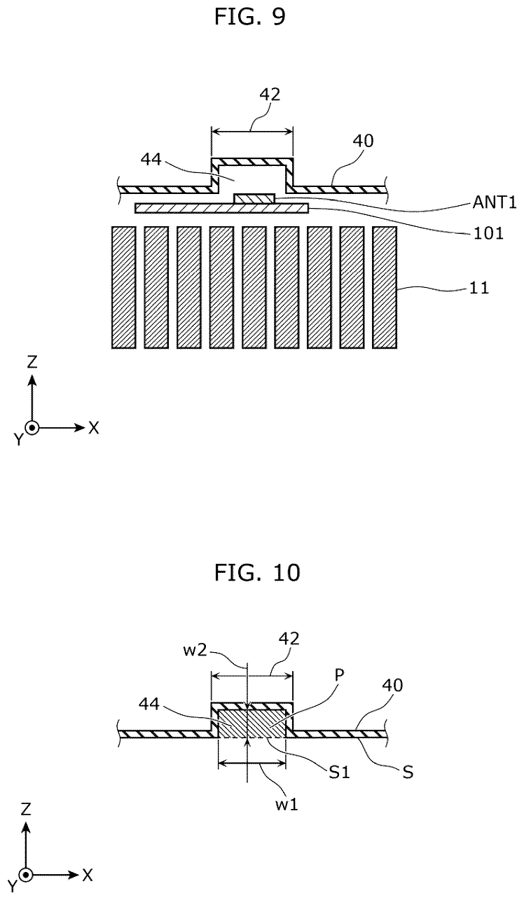

FIG. 9 is a cross-sectional view illustrating one example of a cross-section of BMS 1 taken along line IX-IX illustrated in FIG. 1.

The cross-section of BMS 1 illustrated in FIG. 9 is a cross-section obtained by virtually cutting BMS 1 along a plane parallel to the XZ plane, that is, a plane orthogonal to the direction in which the communication antenna group is aligned (i.e., the Y-axis direction).

The cross-section illustrated in FIG. 9 includes battery cells 11, CMU 101, communication antenna ANT1, and cover 40.

Cover 40 is a cover member that covers the battery assembly, BMU 201, and CMU 101 from above (that is, in positive Z-axis direction relative to the battery assembly, BMU 201, and CMU 101). As one example, when the battery assembly is used as a battery for an automobile, cover 40 may be part of the automobile body structure.

Cover 40 includes conductor 42 in a portion thereof. For example, the material of conductor 42 is, but not limited to, iron or aluminum.

Conductor 42 is positioned to cover at least a portion of the communication antenna group (that is, communication antenna ANT1 and communication antenna ANT2) (see FIG. 1). Note that conductor 42 may be positioned to cover the entire communication antenna group.

Conductor 42 includes recess 44. Recess 44 extends in the direction in which the communication antenna group is aligned (that is, the Y-axis direction) (see FIG. 1). Recess 44 is recessed in a direction away from the antenna group (that is, in the positive Z-axis direction) in the cross-section illustrated in FIG. 9. Stated differently, recess 44 is a recessed portion formed by conductor 42 being recessed in positive Z-axis direction.

FIG. 10 is an explanatory diagram of recess 44 in the cross-sectional view of FIG. 9. The explanation of recess 44 will be continued with reference to FIG. 10.

Recess 44 corresponds to space P enclosed by plane S1, which is a virtual extension of surface S of cover 40, and conductor 42. The cross-sectional shape of recess 44 illustrated in FIG. 10 is rectangular. Recess 44 has a rectangular parallelepiped shape having the cross-sectional shape taken parallel to the XZ plane as illustrated in FIG. 10, and extends in the Y-axis direction.

Recess 44 functions as a waveguide through which radio waves for wireless communication transmitted by the communication antennas (that is, communication antenna ANT1 and communication antenna ANT2) included in the communication antenna group propagate. Here, conductor 42 has a function similar to that of a general rectangular waveguide, and specifically, has a function of inhibiting radio waves propagating through recess 44 functioning as a waveguide from interfering with incoming waves arriving from outside, as well as a function of stably maintaining and propagating radio waves within recess 44. As a result, radio waves transmitted by the communication antennas propagate favorably within recess 44, contributing to inhibiting the quality of the wireless communication by the communication antenna from degrading, or in other words, contributing to maintaining quality without degradation.

Recess 44 may have a characteristic in which one of the width in the Z-axis direction (corresponding to the first direction) of recess 44 or the width in the Y-axis direction (corresponding to the second direction) is longer than the wavelength of the radio waves used for wireless communication by the communication antenna group, and the other is shorter than the wavelength. For example, when the frequency of the radio waves used for wireless communication is 2.4 GHz, the above-mentioned wavelength is approximately 12 cm.

As a specific example, recess 44 may have a characteristic in which width w1 in the X-axis direction is longer than the wavelength, and width w2 in the Z-axis direction is shorter than the wavelength. As another specific example, recess 44 may have a characteristic in which width w2 in the Z-axis direction is longer than the wavelength, and width w1 in the Y-axis direction is shorter than the wavelength.

With this, the propagation mode of radio waves existing and propagating within recess 44 can be made to be TE mode or TM mode. As a result, recess 44 can more stably maintain and propagate radio waves within recess 44, and can further inhibit the quality of the wireless communication by the communication antenna from degrading.

As another specific example, recess 44 may have a characteristic in which width w1 in the X-axis direction is an integer multiple of the wavelength, and width w2 in the Z-axis direction is approximately half the wavelength. With this, recess 44 can more stably maintain and propagate radio waves within recess 44, and can further inhibit the quality of the wireless communication by the communication antenna from degrading.

The material of the portion of cover 40 other than conductor 42 may be a conductive material or a non-conductive material. If the material of the above-mentioned portion is a conductive material, conductor 42, as an integral part of cover 40, contributes to inhibiting the quality of the wireless communication by the communication antenna from degrading, or in other words, contributes to maintaining quality without degradation.

Next, another embodiment of cover 40 will be described.

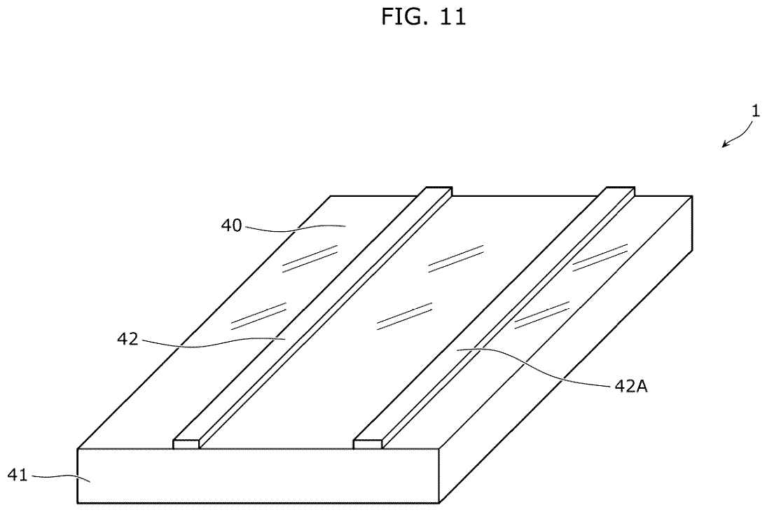

FIG. 11 is a third external view illustrating one example of battery management system 1 according to the present embodiment. In FIG. 11, cover 40 is configured as a part of housing 41 that accommodates the battery assembly.

When the battery assembly is used as a battery for an automobile, housing 41 may be a housing that accommodates that battery. When the battery assembly is used as a general battery (or charge/discharge device), housing 41 may be a housing that accommodates that battery.

Note that housing 41 may be a housing that hermetically accommodates the battery assembly. Hermetically accommodating the battery assembly achieves the advantageous effect of inhibiting water or dust from entering recess 44 that functions as a waveguide.

Embodiments arrived at by a person skilled in the art making various modifications to the embodiment, or embodiments realized by arbitrarily combining elements and functions in the embodiments which do not depart from the essence of the present disclosure are also included in the present disclosure.

### Additional Information

The following techniques are disclosed by the description of the above embodiment.

(Technique 1) A battery management system for managing a battery assembly, including: a management circuit that manages the battery assembly and includes a first communication antenna; and one or more monitoring circuits that monitor the battery assembly and each include a second communication antenna that communicates with the first communication antenna. A communication antenna group including the first communication antenna and one or more second communication antennas is aligned in a straight line, each of the one or more second communication antennas being the second communication antenna. The battery management system further includes a conductor that covers at least part of the communication antenna group. The conductor includes a recess that extends in an alignment direction of the communication antenna group and is recessed in a direction away from the communication antenna group in a cross-section orthogonal to the alignment direction.

According to the above aspect, the recess functions as a waveguide for radio waves used for wireless communication by the communication antenna group. The recess has a function of inhibiting radio waves propagating within the recess from interfering with incoming waves from outside, as well as a function of stably maintaining radio waves within the recess. As a result, radio waves transmitted by the communication antennas propagate favorably within the recess, contributing to inhibiting the quality of the wireless communication between the communication antennas from degrading, or in other words, contributing to maintaining quality without degradation. Accordingly, the battery management system can inhibit degradation of wireless communication quality.

(Technique 2) The battery management system according to Technique 1, wherein one of a width of the recess in a first direction away from the communication antenna group or a width of the recess in a second direction orthogonal to the first direction in the cross-section is longer than a wavelength of a radio wave used for wireless communication by the communication antenna group, and an other of the width of the recess in the first direction or the width of the recess in the second direction is shorter than the wavelength.

According to the above aspect, the recess can make the propagation mode of radio waves existing within the recess to be TE mode or TM mode. As a result, radio waves can propagate more stably within the recess, and the wireless communication by the communication antenna can be stabilized. Accordingly, the battery management system can further inhibit degradation of wireless communication quality.

(Technique 3) The battery management system according to Technique 1 or 2, wherein the recess has a rectangular shape in the cross-section.

According to the above aspect, radio waves can be more stably maintained within the recess, contributing to inhibiting degradation of wireless communication quality. There is also the advantage that the conductor becomes easier to design. Accordingly, the battery management system can inhibit degradation of wireless communication quality.

(Technique 4) The battery management system according to any one of Techniques 1 to 3, wherein the conductor is part of a cover member that covers the battery assembly, the management circuit, and the one or more monitoring circuits.

According to the above aspect, the battery management system can more easily inhibit degradation of wireless communication quality by using a cover member that covers the battery assembly, the management circuit, and one or more monitoring circuits.

(Technique 5) The battery management system according to any one of Techniques 1 to 3, wherein the conductor is part of a housing that accommodates the battery assembly.

According to the above aspect, the battery management system can more easily inhibit degradation of wireless communication quality by using a conductor that is a part of the housing accommodating the battery assembly.

(Technique 6) The battery management system according to any one of Techniques 1 to 3, wherein the conductor is part of a body structure of an automobile equipped with the battery assembly.

According to the above aspect, the battery management system can more easily inhibit degradation of wireless communication quality by using a conductor that is a part of the body structure of the automobile equipped with the battery assembly.

(Technique 7) The battery management system according to any one of Techniques 1 to 3, wherein the conductor is part of a housing that hermetically accommodates the battery assembly.

According to the above aspect, the battery management system can inhibit water or dust from entering the recess functioning as a waveguide for wireless communication by using a conductor that is a part of the housing hermetically accommodating the battery assembly, and can prevent degradation of communication quality due to the entry of water or dust. Accordingly, the battery management system can more easily inhibit degradation of wireless communication quality.

### INDUSTRIAL APPLICABILITY

The present disclosure is applicable to a battery management system or the like in which wireless communication is performed within the system.

1. A battery management system for managing a battery assembly, the battery management system comprising:
a management circuit that manages the battery assembly and includes a first communication antenna; and
one or more monitoring circuits that monitor the battery assembly and each include a second communication antenna that communicates with the first communication antenna, wherein
a communication antenna group including the first communication antenna and one or more second communication antennas is aligned in a straight line, each of the one or more second communication antennas being the second communication antenna,
the battery management system further comprises a conductor that covers at least part of the communication antenna group, and
the conductor includes a recess that extends in an alignment direction of the communication antenna group and is recessed in a direction away from the communication antenna group in a cross-section orthogonal to the alignment direction.

2. The battery management system according to claim 1, wherein
one of a width of the recess in a first direction away from the communication antenna group or a width of the recess in a second direction orthogonal to the first direction in the cross-section is longer than a wavelength of a radio wave used for wireless communication by the communication antenna group, and an other of the width of the recess in the first direction or the width of the recess in the second direction is shorter than the wavelength.

3. The battery management system according to claim 1, wherein
the recess has a rectangular shape in the cross-section.

4. The battery management system according to claim 1, wherein
the conductor is part of a cover member that covers the battery assembly, the management circuit, and the one or more monitoring circuits.

5. The battery management system according to claim 1, wherein
the conductor is part of a housing that accommodates the battery assembly.

6. The battery management system according to claim 1, wherein
the conductor is part of a body structure of an automobile equipped with the battery assembly.

7. The battery management system according to claim 1, wherein
the conductor is part of a housing that hermetically accommodates the battery assembly.
